(19) United States
(12) Patent Application Publication
(10) Pub. No.: US 2022/0093619 A1
(43) Pub. Date: Mar. 24, 2022

(54) MEMORY STRUCTURE AND METHOD OF MANUFACTURING THE SAME

(71) Applicant: Winbond Electronics Corp., Taichung City (TW)

(72) Inventor: Wen-Chieh TSAI, Taichung City (TW)

(21) Appl. No.: 17/025,164

(22) Filed: Sep. 18, 2020

(51) Int. Cl. H01L 27/11521; H01L 21/3215; H01L 21/28

(52) U.S. Cl. CPC H01L 27/11521; H01L 21/32139; H01L 21/28114; H01L 21/32155

(57) ABSTRACT

A memory structure and its manufacturing method are provided. The memory structure includes a substrate having active regions, wherein adjacent active regions are separated by an isolation structure. The memory structure includes several stacked structures disposed on the active regions, respectively. Each of the stacked structures includes a tunnel dielectric layer on the substrate and a floating gate on the tunnel dielectric layer. The floating gate includes a lower silicon layer and an upper silicon layer, wherein the lower silicon layer includes one or more dopants selected from nitrogen gas, carbon, or a combination thereof. The upper silicon layer is disposed on the lower silicon layer.

### BACKGROUND

### Field of the Disclosure

The present disclosure relates to a memory structure and a method of manufacturing the same, and in particular, it relates to a non-volatile memory structure and a method of manufacturing the same.

### Description of the Related Art

Non-volatile memory structures can be categorized into two types, according to their write mechanism: read-only memory (ROM) and flash memory. Categorization is dependent upon whether the data in the memory can be rewritten at any time. Although flash memory does not offer arbitrary random-access rewrite or erase operations, it offers random-access read and programming operations. Also, flash memory costs much less than read-only memory and had become the dominant memory type wherever a system requires a significant amount of non-volatile solid-state storage.

In general, a flash memory contains two gates. One gate is a floating gate for storing data, and the other gate is a control gate for input and output of data. The floating gate is positioned under the control gate and is in a “floating” state. The so-called “floating” means that this gate is surrounded and isolated with an insulating material to prevent loss of charge. The control gate is electrically connected to the word line to control the device. One of the advantages of flash memory is that one or more selected blocks or sections can be entirely erased. Flash memory is widely used in enterprise servers, storage and networking technologies, and a variety of consumer electronics, such as universal serial bus (USB) flash drives, mobile phones, digital cameras, tablets, personal computer memory cards for laptops and embedded controllers.

Although existing non-volatile memory structures and methods of manufacturing the same have generally been adequate for their intended purposes, they have not been entirely satisfactory in all respects. There are still some problems to be overcome in regards to the memory structures and its manufacturing methods.

### SUMMARY

In some embodiments of the disclosure, a memory structure is provided.

The memory structure includes a substrate and several stacked structures on the substrate, wherein the substrate has several active regions, and the stacked structures are on the respective active regions. Also, each of the stacked structures includes a tunnel dielectric layer on the substrate and a floating gate on the tunnel dielectric layer. In some embodiments, the floating gate includes a lower silicon layer on the tunnel dielectric layer, and an upper silicon layer on the lower silicon layer. Also, in some embodiments, the lower silicon layer of the floating gate includes one or more dopants containing nitrogen gas, carbon, or a combination thereof

In some embodiments, the lower silicon layer of the floating gate includes the implantation of nitrogen gas at a doping concentration of 1*10²⁰/cm³ to 1*10²²/cm³.

In some embodiments, the lower silicon layer of the floating gate has a first average grain size, and the upper silicon layer has a second average grain size. The first average grain size is smaller than the second average grain size.

In some embodiments of the disclosure, a method of manufacturing a memory structure is provided. The method includes providing a substrate having several active regions and forming several stacked structures on the respective active regions. Each of the stacked structures includes a tunnel dielectric layer on the substrate and a floating gate on the tunnel dielectric layer. In some embodiments, the floating gate includes a lower silicon layer on the tunnel dielectric layer, and an upper silicon layer on the lower silicon layer. Also, the lower silicon layer of the floating gate includes one or more dopants containing nitrogen gas, carbon, or a combination thereof. In some embodiments, the method also includes forming several trenches respectively between the active regions. In some embodiments, the method further includes forming isolation structures in the trenches.

In some embodiments, steps of forming the floating gate include depositing a first silicon layer on the tunnel dielectric layer; implanting the dopants containing nitrogen gas, carbon, or a combination thereof in the first silicon layer; and depositing a second silicon layer on the first silicon layer.

In some embodiments, after the second silicon layer is deposited on the first silicon layer, the second silicon layer and the first silicon layer are patterned in the same etching step, so that the upper silicon layer and the lower silicon layer are formed, respectively.

### BRIEF DESCRIPTION OF THE DRAWINGS

The present disclosure can be further understood by reading the subsequent detailed description and examples with references made to the accompanying drawings, wherein:

FIG. 1A-FIG. 10 are cross-sectional views of various stages of manufacturing a memory structure in accordance with some embodiments of the present invention.

FIG. 2 is a cross-sectional view of a memory structure in accordance with some embodiments of the present invention.

### DETAILED DESCRIPTION

The present disclosure is described in detail with reference to the figures of the embodiments of the present disclosure. It should be appreciated, however, that the present disclosure can be embodied in a wide variety of implements and is not limited to embodiments described in the disclosure. Various features may be arbitrarily drawn at different scales for the sake of simplicity and clarity. Some embodiments are described below. Throughout the various views and illustrative embodiments, similar reference numbers are used to designate similar features/components. In addition, in order to simplify the descriptions, the drawings used in the embodiments only depict four stacked structures with floating gates on the substrate for illustration of a memory structure, and a control gate extends above those floating gates. However, the present disclosure does not limit the actual numbers of the stacked structures of a memory structure in the application. A memory structure may include several stacked structures as provided in the embodiments. Also, the memory structures in accordance with some embodiments can be different types of non-volatile memory structures. The memory structures in accordance with some embodiments can be applied to any memory structure containing a floating gate.

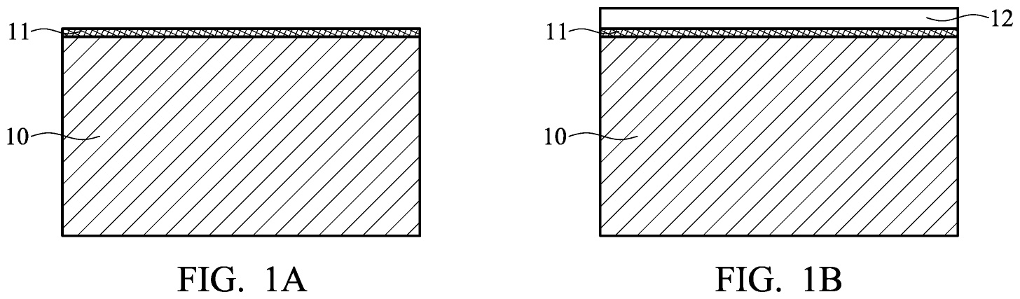

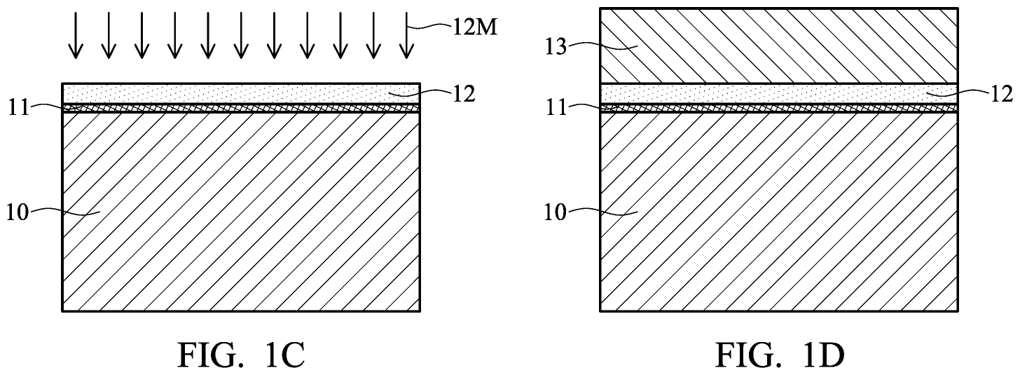

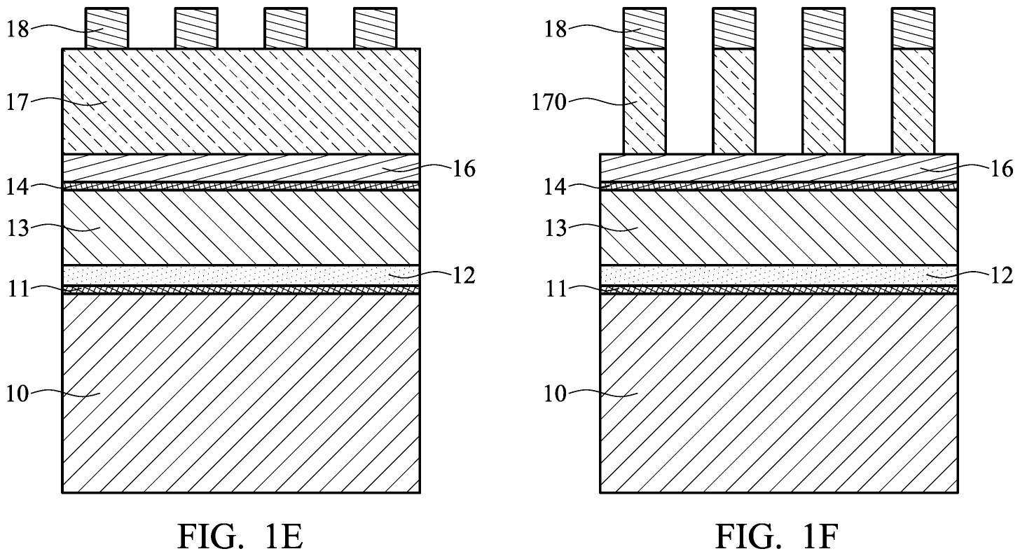

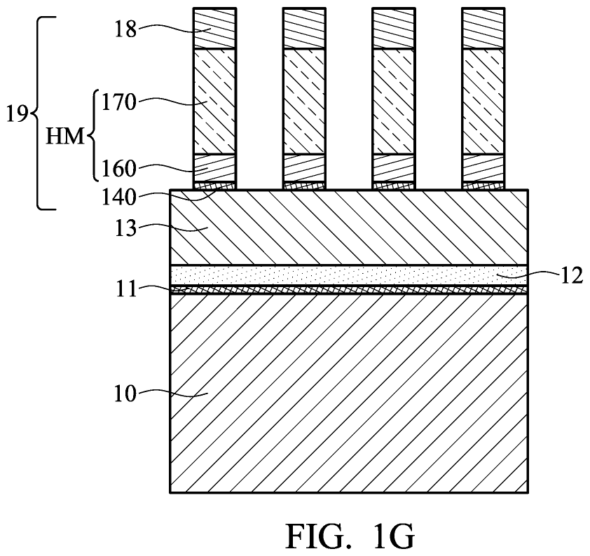

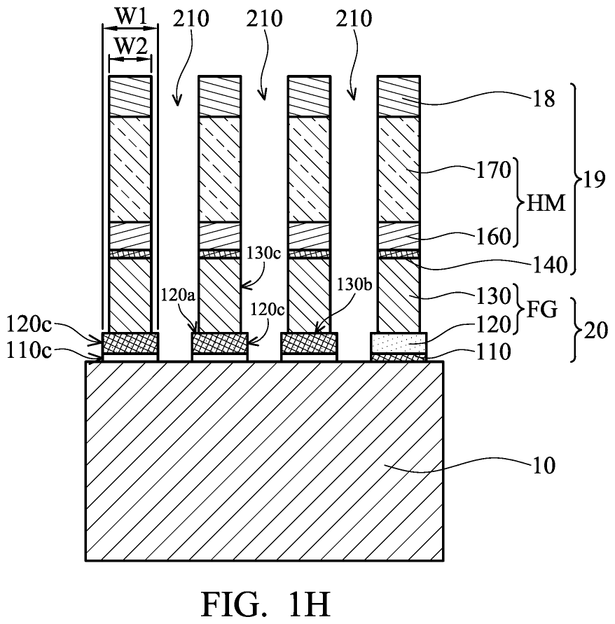

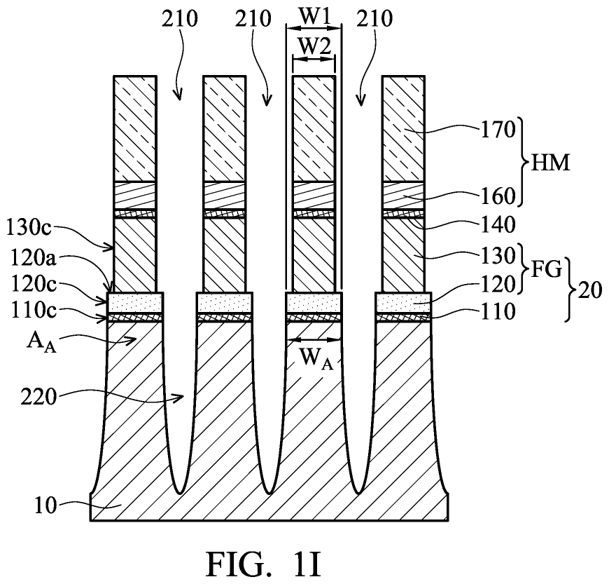

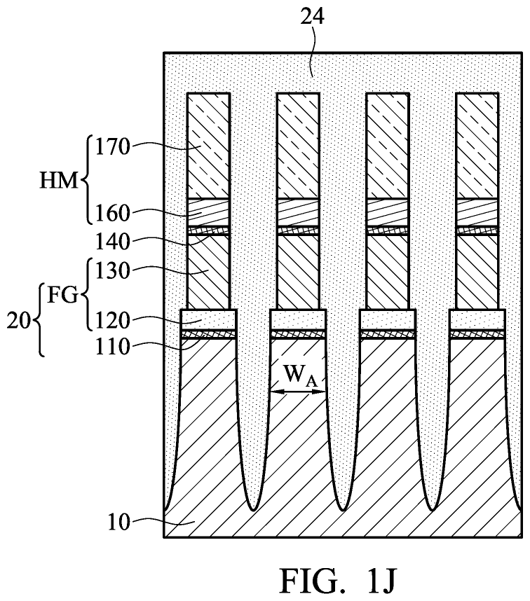

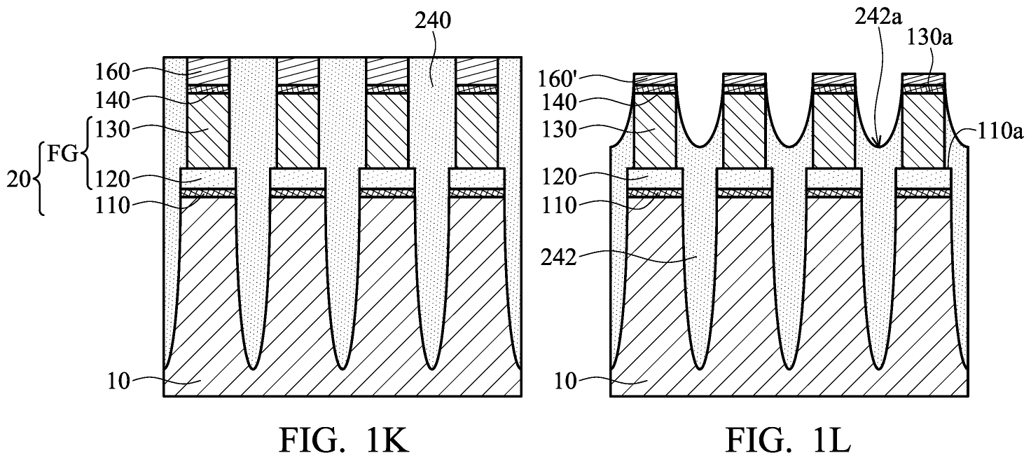

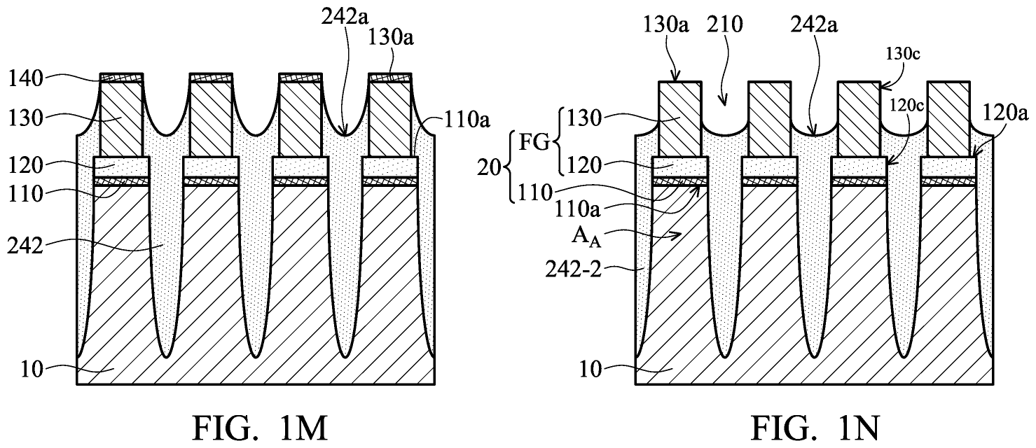

FIG. 1A-FIG. 10 are cross-sectional views of various stages of manufacturing a memory structure in accordance with some embodiments of the present invention. Referring to FIG. 1A, a substrate 10 is provided. The substrate 10 includes a source region and a drain region (not shown in FIG. 1A-FIG. 10). In some embodiments, the substrate 10 may include silicon, gallium arsenide, gallium nitride, germanium silicide, a semiconductor-on-insulator (SOI), another suitable substrate material, or a combination thereof.

Next, a tunnel dielectric material layer 11 is formed on the substrate 10. The tunnel dielectric material layer 11 may include silicon oxide or another high-k dielectric material (with a dielectric constant greater than 4). For example, the high-k dielectric material may include hafnium oxide, hafnium silicon oxide, hafnium aluminum oxide, or hafnium tantalum oxide. In some embodiments, the thickness of the tunneling dielectric material layer 11 is in a range of about 3 nm to about 10 nm.

Referring to FIG. 1B, a silicon layer 12 is formed on the tunneling dielectric material layer 11. The silicon layer 12 may be an amorphous silicon layer, and can be formed by deposition. In some embodiments, the thickness of the silicon layer 12 is in a range of about 10 nm to about 30 nm, such as about 20 nm.

Next, referring to FIG. 1C, an implantation process 12M is performed to implant the dopants into the silicon layer 12. For example, the silicon layer 12 is implanted by one or more dopants containing nitrogen gas, carbon, or a combination thereof. In some embodiments, nitrogen gas is implanted into the silicon layer 12 (as shown in FIG. 1C), and the dose of nitrogen is in a range of 1*10¹⁵ atom/cm² to 4*10¹⁵ atom/cm². In some embodiments, the implantation energy of nitrogen gas is in a range of about 2 KJ to about 5 KJ, such as about 3 KJ. Also, in some other embodiments, one or more N-type dopants, such as phosphorus (P), can be implanted into the silicon layer 12 to form a floating gate having an N-type conductivity in the subsequent processes.

Referring to FIG. 1D, another silicon layer 13 is formed on the silicon layer 12. The silicon layer 13 may include polysilicon, and can be formed by deposition. In some embodiments, the silicon layer 13 may be an undoped polysilicon layer. Also, in some embodiments, the thickness of the silicon layer 13 is in a range of about 40 nm to about 100 nm, such as about 60 nm.

Next, referring to FIG. 1E, an oxide layer 14, a mask layer 16, another mask layer 17 and a patterned photoresist 18 are sequentially formed on the silicon layer 13. The oxide layer 14 may include silicon oxide or silicon oxynitride, and can be formed by thermal oxidation, chemical vapor deposition (CVD), another suitable deposition method, or a combination thereof In some embodiments, the thickness of the oxide layer 14 is in a range of about 5 nm to about 15 nm. Also, the mask layer 16 may include silicon nitride or silicon oxynitride, and the mask layer 17 may include silicon oxide. The mask layers 16 and 17 can be formed by chemical vapor deposition (CVD) or another suitable deposition method.

Referring to FIG. 1F, an etching process such as anisotropic etching process is performed to remove the portions of the mask layer 17 exposed by the patterned photoresist 18, thereby forming a patterned mask layer 170. In one embodiment, the exposed portions of the mask layer 17 can be removed by a dry etching process.

Next, referring to FIG. 1G, another anisotropic etching process is further performed to remove the exposed portions of the mask layer 16 and the oxide layer 14 by a mask that includes the patterned photoresist 18 and the patterned mask layer 170, thereby forming a patterned mask layer 160 and a patterned oxide layer 140. In one embodiment, the exposed portions of the mask layer 16 and the oxide layer 14 can be removed by a dry etching process. Accordingly, several stacked structures 19 are formed on the silicon layer 13, as shown in FIG. 1G. In addition, the silicon layer 13 functions as an etch stop layer during the removal of the exposed portions of the oxide layer 14. In this embodiment, the patterned mask layer 170 and the patterned mask layer 160 form a stack of patterned masks HM that is a multilayer structure. However, the present invention is not limited in this embodiment, which illustrates a multilayer structure of the stack of patterned masks. In some other embodiments, a patterned mask for removing the exposed portions of the oxide layer 14 can be a single layer structure.

Referring to FIG. 1H, after the stacked structures 19 are formed on the silicon layer 13, the silicon layers 13 and 12 are patterned in the same etching step to respectively form several upper silicon layers 130 and several silicon layers 120 of the floating gates FG. Also, several openings 210 are formed between adjacent stacked structures 19 and adjacent floating gates FG. The openings 210 expose portions of the tunnel dielectric material layer 11. In some embodiments, the silicon layers 13 and 12 are patterned by a dry etching process such as a reactive ion etching process, or a self-aligned double patterning (SADP) process, or a combination of the reactive ion etching process and the self-aligned double patterning process.

It is worth noting that an etching rate of the silicon layer 12 is lower than an etching rate of the silicon layer 13 because of dopants such as nitrogen gas, carbon, phosphorous, or a combination thereof implanted into the silicon layer 12. Therefore, the width W1 of the lower silicon layer 120 is greater than the width W2 of the upper silicon layer 130.

In some embodiments, the ratio (W1/W2) of the width W1 of the lower silicon layer 120 to the width W2 of the upper silicon layer 130 is greater than 1.0 and less than or equal to 1.5 (1.0<W1/W2<1.5). For example, the ratio (W1/W2) of the width W1 to the width W2 is about 1.1. The doping concentration of the dopants in the silicon layer 12 can be adjusted and selected for making the lower silicon layer 120 and the upper silicon layer 130 having a required ratio of the width W1 to the width W2 (W1/W2), thereby complying with the requirements in the applications. For example, when the doping concentration of the dopants in the silicon layer 12 is increased, the etching rate of the silicon layer 12 is decreased, resulting in the greater width W1 of the lower silicon layer 120. That is, the ratio (W1/W2) of the width W1 to the width W2 can be modified by adjusting the doping concentration of the dopants in the silicon layer 12 to meet the requirements in the applications.

Next, referring to FIG. 11, the patterned photoresist 18 is removed. Then, the exposed tunnel dielectric material layer 11 and the substrate 10 below are etched using a mask formed by the stacks of patterned masks HM, the patterned oxide layer 140 and the floating gate FG, thereby forming several trenches 220 in the substrate 10. As shown in FIG. 11, the region between adjacent trenches 220 can be an active region A_{A} of a memory structure. Also, a dielectric pattern can be formed after etching the tunnel dielectric material layer 11, wherein the patterned tunnel dielectric material layer functions as a tunnel dielectric layer 110 in the memory structure. In one embodiment, the sidewall 120c of the lower silicon layer 120 is substantially aligned with the sidewall 110c of the tunnel dielectric layer 110. Also, each of the stacked structures 20 includes the tunnel dielectric layer 110 on the substrate 10 and the floating gate FG on the tunnel dielectric layer 110.

It is worth noting that an etching rate of the lower silicon layer 120 is lower than an etching rate of the substrate 10 because of the lower silicon layer 120 containing dopants. Therefore, the width W1 of the lower silicon layer 120 is substantially equal to the width W_{A} of the active region A_{A}, and the width W1 of the lower silicon layer 120 is greater than the width W2 of the upper silicon layer 130.

Next, referring to FIG. 1J, an isolation material layer 24 is deposited on the stacks of patterned masks HM, the patterned oxide layer 140 and the stacked structures 20. Also, the isolation material layer 24 fills the trenches 220 and the openings 210. In some embodiments, the isolation material layer 24 as filled in the openings 210 may reach the opposite sides of the stacks of patterned masks HM, or cover the top surfaces of the stacks of patterned masks HM (as shown in FIG. 1J). The isolation material layer 24 includes one or more insulating materials, such as silicon oxide, silicon nitride, or a combination thereof. Also, the isolation material layer 24 can be formed by chemical vapor deposition (CVD) or another suitable deposition method.

Referring to FIG. 1K, a portion of the isolation material layer 24 and the patterned mask layer 170 are removed. The remaining portion of the isolation material layer 240 is positioned on opposite sides of the patterned mask layer 160. Also, the top surface of the remaining portion of the isolation material layer 240 is substantially level with the top surface of the patterned mask layer 160. In one embodiment, the portion of the isolation material layer 24 and the patterned mask layer 170 can be removed by chemical mechanical polishing (CMP).

Then, referring to FIG. 1L, the first etching step performed to remove a portion of the isolation material layer 240. As shown in FIG. 1L, the isolation material layer 240 is recessed. The remaining portions of the isolation material layer in the openings 210 and the trenches 220 form an isolation structure 242. In addition, a portion of the patterned mask layer 160 is also removed by the first etching step. A portion of the isolation material layer 240 can be removed by anisotropic etching, such as a dry etching process. In some embodiments, it can be controlled that the top surface 242a of the isolation structure 242 is lower than the top surface 130a of the upper silicon layer 130, thereby increasing the gate-coupling ratio (GCR) between the floating gate FG and a conductive layer functioning as a control gate. In addition, it can be controlled that the top surface 242a of the isolation structure 242 is higher than the top surface 110a of the tunnel dielectric layer 110, thereby preventing the tunnel dielectric layer 110 from damage during formation of the isolation structure 242.

Referring to FIG. 1M, the patterned mask layer 160′ that remains on the patterned oxide layer 140 after performing the first etching step is removed.

Referring to FIG. 1N, the second etching step is performed to further remove a portion of the isolation structure 242 and the patterned oxide layer 140, thereby forming another isolation structure 242-2. In some embodiments, the portion of the isolation structure 242 and the patterned oxide layer 140 can be removed by a dry etching process.

According to the embodiments, the lower silicon layer 120 of different floating gates FG can have a uniform height by controlling the deposition thickness of the silicon layer 12. Further, the uniformity of the depth of the recessed isolation material layer 240 between the floating gates FG as shown in FIG. 1L can be effectively controlled, so that the levels of the top surfaces of the isolation structure between the active regions A_{A} (such as the isolation structure 242 or the isolation structure 242-2) are highly uniform.

Referring to FIG. 1O, an inter-gate dielectric layer 27 is conformally formed on the floating gates FG, and a conductive layer 28 is deposited on the inter-gate dielectric layer 27 as a control gate of the memory structure. The inter-gate dielectric layer 27 can be a single layer structure or a multilayer structure. In some embodiments, the inter-gate dielectric layer 27 includes silicon oxide, silicon nitride, or a combination thereof. For example, the inter-gate dielectric layer 27 may be an oxide-nitride-oxide (ONO) structure, or an oxide-nitride-oxide-nitride-oxide (ONONO) structure. Also, the conductive layer 28 can be a single layer structure or a multilayer structure. The conductive layer 28 may include polysilicon, metal, metal silicide or other conductive materials. For example, metal may include titanium (Ti), tantalum (Ta), tungsten (W), aluminum (Al), zirconium (Zr), or a combination thereof. Metal silicide may include nickel silicide, titanium silicide, or tungsten silicide. Accordingly, after aforementioned manufacturing steps are performed, a memory structure in accordance with some embodiments is completed.

In some embodiments, nitrogen gas is implanted in the silicon layer 12 (as shown in FIG. 1C). It is worth noting that a high and uniform doping concentration of nitrogen gas in the lower silicon layer 120 can be achieved. For example, in a final memory structure, the lower silicon layer 120 of the floating gate FG as manufactured in accordance with some embodiments includes the implantation of nitrogen gas at a doping concentration of 1*10²⁰/cm³ to 1*10²²/cm³.

In some embodiments, the silicon layer 12 originally formed of amorphous silicon will be transformed into polysilicon after a thermal process performed in the fabrication of the memory structure. Thus, both the lower silicon layer 120 and the upper silicon layer 130 of the floating gate FG in the memory structure as shown in FIG. 10 include polysilicon. Also, dopants containing nitrogen gas, carbon, or a combination thereof in the silicon layer 12 also make the grain size of the polysilicon formed later in the lower silicon layer 120 be smaller than the grain size of the polysilicon in the upper silicon layer 130, wherein the silicon layer 13 does not include any dopant of nitrogen or carbon.

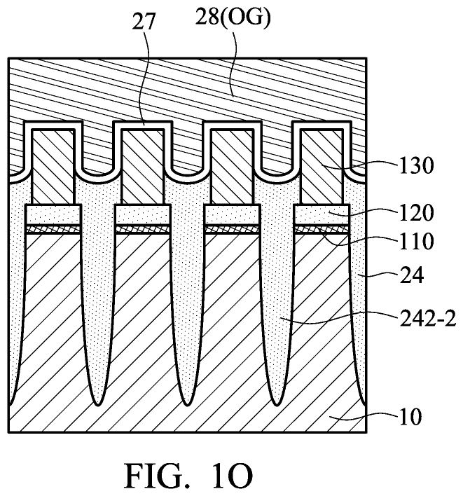

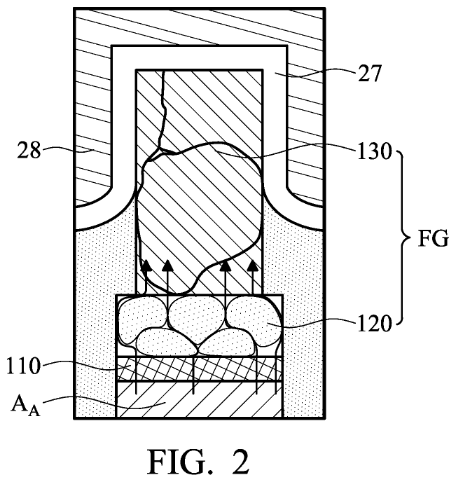

FIG. 2 is a cross-sectional view of a memory structure in accordance with some embodiments of the present invention. As shown in FIG. 2, the lower silicon layer 120 of the floating gate FG has a first average grain size, the upper silicon layer 130 of the floating gate FG has a second average grain size, and the first average grain size is smaller than the second average grain size. In one embodiments, the first average grain size is in a range of about 5 nm to about 20 nm, and the second average grain size is in a range of about 50 nm to about 80 nm. The smaller the grain size and the more grain boundaries, the more paths can be provided for the flow of the electrons, so that more stable the electrons jump over the tunnel dielectric layer 110 and into the floating gate FG. Therefore, when the memory structure is in a writing operation, the current as generated flowing through the channel of the active region A_{A} can be steadily injected into the floating gate FG, and the paths of the current flowing through the tunnel dielectric layer 110 can be increased and dispersed. After several cycles of write operation and erase operation are performed, the tunnel dielectric layer 110 is not easily damaged and has a good property. Thus, according to the memory structure in accordance with some embodiments, data stored in the floating gate of the memory structure is less likely to be lost.

According to the foregoing embodiments, the topology of the floating gate can be stably controlled. Specifically, by implanting dopants such as nitrogen gas, carbon, phosphorus, or a combination thereof into the silicon layer 12, the width of the lower silicon layer 120 of each floating gate FG can be greater than the width of the upper silicon layer 130 of each floating gate FG, and the width of an active region A_{A} under the floating gate FG can be substantially equal to the width of the lower silicon layer 120 of each floating gate FG. For adjacent floating gates FG, the distance between adjacent upper silicon layers 130 is greater than the distance between adjacent lower silicon layers 120, thereby decreasing the coupling between adjacent upper silicon layers 130 of adjacent floating gates FG. Also, since both the width of the lower silicon layer 120 of the floating gate FG and the width of the active region A_{A} are greater than the width of the upper silicon layers 130, the area of the channel in the active region A_{A} can be increased, and more electrons can flow through the channel and be injected onto the floating gate FG, thereby decreasing the operating voltage. That is, more operating current can flow through the channel having a larger area. In addition, since the lower silicon layer 120 has smaller average grain size and more grain boundaries, the electrons can be more steadily injected into the floating gate FG. Accordingly, the electrical performance of the memory structure can be improved.

According to the aforementioned memory structure and its manufacturing method in accordance with some embodiments, a lower silicon layer on the tunnel dielectric layer includes one or more dopants containing nitrogen gas, carbon, or a combination thereof. In the subsequent process, this lower silicon layer forms a lower portion of a floating gate. According to the method of manufacturing the memory structure in accordance with some embodiments, the topology of the floating gate can be stably controlled. For example, the width of the lower silicon layer, the width of the active region and the height of the isolation structure between the floating gates can be well-controlled. Thus, the memory structure as manufactured in accordance with some embodiments has several advantages, such as accelerating the speed of the write operation, reducing the operating voltage during the write operation, improving the stability of the data storage, etc. In addition, the memory structure in accordance with some embodiments has a relatively stable electrical performance. Consequently, the yield and reliability of the final product can be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory structure, comprising:
a substrate having active regions, wherein adjacent active regions are separated by an isolation structure;
stacked structures on the respective active regions, wherein each of the stacked structures comprises a tunnel dielectric layer on the substrate and a floating gate on the tunnel dielectric layer, and the floating gate comprises:
a lower silicon layer on the tunnel dielectric layer, wherein the lower silicon layer includes one or more dopants containing nitrogen gas, carbon, or a combination thereof; and
an upper silicon layer on the lower silicon layer.

2. The memory structure as claimed in claim 1, wherein the lower silicon layer includes the implantation of nitrogen gas at a doping concentration of 1*10²⁰/cm³ to 1*10²²/cm³.

3. The memory structure as claimed in claim 1, wherein the lower silicon layer of the floating gate has a first average grain size, the upper silicon layer has a second average grain size, and the first average grain size is smaller than the second average grain size.

4. The memory structure as claimed in claim 1, wherein a width of the lower silicon layer is greater than a width of the upper silicon layer.

5. The memory structure as claimed in claim 1, wherein a ratio of a width of the lower silicon layer to a width of the upper silicon layer is greater than 1.0 and less than or equal to 1.5.

6. The memory structure as claimed in claim 1, further comprising:
an inter-gate dielectric layer on the floating gates of each of the stacked structures; and
a control gate on the inter-gate dielectric layers of the stacked structures.

7. A method of manufacturing a memory structure, comprising:
providing a substrate having active regions;
forming stacked structures on the respective active regions, wherein each of the stacked structures comprises a tunnel dielectric layer on the substrate and a floating gate on the tunnel dielectric layer, and the floating gate comprises:
a lower silicon layer on the tunnel dielectric layer, wherein the lower silicon layer includes one or more dopants containing nitrogen gas, carbon, or a combination thereof; and
an upper silicon layer on the lower silicon layer;
forming trenches respectively between the active regions; and
forming isolation structures in the trenches.

8. The method of manufacturing the memory structure as claimed in claim 7, wherein the lower silicon layer includes the implantation of nitrogen gas at a doping concentration of 1*10²⁰/cm³ to 1*10²²/cm³.

9. The method of manufacturing the memory structure as claimed in claim 7, wherein the lower silicon layer of the floating gate has a first average grain size, the upper silicon layer has a second average grain size, and the first average grain size is smaller than the second average grain size.

10. The method of manufacturing the memory structure as claimed in claim 7, wherein forming the floating gate comprises:
depositing a first silicon layer on the tunnel dielectric layer;
implanting the one or more dopants containing nitrogen gas, carbon, or a combination thereof in the first silicon layer; and
depositing a second silicon layer on the first silicon layer.

11. The method of manufacturing the memory structure as claimed in claim 10, wherein nitrogen gas is implanted in the first silicon layer, and a dose of nitrogen gas is in a range of 1*10¹⁵ atom/cm² to 4*10¹⁵ atom/cm².

12. The method of manufacturing the memory structure as claimed in claim 10, wherein after the second silicon layer is deposited on the first silicon layer, the second silicon layer and the first silicon layer are patterned in the same etching step to form the upper silicon layer and the lower silicon layer, respectively.

13. The method of manufacturing the memory structure as claimed in claim 12, wherein an etching rate of the first silicon layer is lower than an etching rate of the second silicon layer when the etching step is performed.

14. The method of manufacturing the memory structure as claimed in claim 7, wherein a width of the lower silicon layer of the floating gate is greater than a width of the upper silicon layer of the floating gate.

15. The method of manufacturing the memory structure as claimed in claim 7, wherein a ratio of a width of the lower silicon layer to a width of the upper silicon layer is greater than 1.0 and less than or equal to 1.5.
